(19) United States
(12) Patent Application Publication
(10) Pub. No.: US 2026/0318976 A1
(43) Pub. Date: Oct. 15, 2026

(54) Method and System for Electrical Test

(71) Applicant: ABB Schweiz AG, Baden (CH)

(72) Inventors: Dongsheng Mei, Shanghai (CN); Huiqin Xu, Shanghai (CN); Shaofeng Gao, Shanghai (CN); Ying Liu, Shanghai (CN); Yonghua Shi, Shanghai (CN); Yonghua Shan, Shanghai (CN); Yin Tian, Shanghai (CN)

(21) Appl. No.: 19/700,540

(22) Filed: Jun. 8, 2026

Related U.S. Application Data
(63) Continuation of application No. PCT/CN2023/137664, filed on Dec. 8, 2023.

(51) Int. Cl. G01R 31/12; G01R 31/16; G01R 31/18; H01M 10/42

(52) U.S. Cl. CPC G01R 31/1263; G01R 31/16; G01R 31/18; H01M 10/4285

(57) ABSTRACT

A method for electrical test includes receiving a set of coordinates for an object, receiving information indicating a number of test contacts of an apparatus for the electrical test, determining, based on the number of the test contacts, at least one subset of the received set of coordinates, selecting a first subset from the at least one subset, moving the object to a position where a first group of points of the object corresponding to the coordinates in the first subset are accessible by the test contacts, applying an input signal to the first group of points, and generating a response to an output signal relating to the input signal.

### TECHNICAL FIELD

Embodiments of the present disclosure generally relate to a method for electrical test as well as a system for electrical test.

### BACKGROUND

As global energy and environment become increasingly severe, new energy vehicle is an inevitable trend in the development of the automotive industry. Battery tray is an important part of a power system of the new energy vehicle. The battery tray serves as a carrier of a battery module and other parts of the vehicle. Electrical performance of the battery tray has an important influence on the safety of the new energy vehicle and the battery module and other parts carried thereon.

A coating is formed on the battery tray to ensure the electrical performance of the battery tray. For example, some special materials may be sprayed on the designated surfaces of the battery tray, so that the battery tray has performance of insulation and fire resistance. However, due to the existing production conditions, there may be oil, dust, welding spatter and other impurities on the surfaces of the battery tray. Moreover, there may be burrs on spot-welding spots and uneven coating spray thickness. Thus, the insulation performance of battery tray needs to be tested.

### SUMMARY

Embodiments of the present disclosure provide a method for electrical test as well as a system for electrical test.

In a first aspect, a method for electrical test is provided. The method comprises: receiving a set of coordinates for an object; receiving information indicating a number of test contacts of an apparatus for the electrical test; determining, based on the number of the test contacts, at least one subset of the received set of coordinates; selecting a first subset from the at least one subset; moving the object to a position where a first group of points of the object corresponding to the coordinates in the first subset are accessible by the test contacts; applying an input signal to the first group of points, and generating a response to an output signal relating to the input signal.

By applying each point on the object to be tested with the input signal from a respective test contact and generating the respective response, the electrical performance of the whole surface of the object may be accurately determined. Furthermore, a further process, such as fixing the unqualified point, may be performed based on the generated response. In this way, the efficiency of detecting and fixing the object may also be improved. It also provides benefits for the production of the object.

In one or more embodiments, applying an input signal to the first group of points may comprise in response to a determination that one subset of the at least one subset comprises same coordinates as included in the first subset, disabling the application of the input signal to the points corresponding to the same coordinates.

In one or more embodiments, the method may further comprise determining a second subset based on a similarity between the first subset and another subset of the at least subset.

In one or more embodiments, the coordinates are coordinates in a two dimensional coordinate system. In one example, the coordinate may be represented with ([distance relative to origin], [angle]). In another example, the coordinate may be represented with ([x-axis coordinate], [y-axis coordinate]). In case the coordinate is in form of ([x-axis coordinate], [y-axis coordinate]), the similarity may be related to at least one of an x-axis coordinate of the first subset, or a y-axis coordinate of the first subset.

In one or more embodiments, the method further comprises determining a second subset based on the first subset and a predefined offset.

In one or more embodiments, the number of the coordinates in each of the at least one subset corresponds to the number of test contacts.

In one or more embodiments, applying the input signal to the first group of points further comprises: enabling a portion of the test contacts, and simultaneously disabling the remainder of the test contacts.

In one or more embodiments, applying the input signal to the first group of points further comprises selectively switching on the test contacts.

In one or more embodiments, the method further comprises in response to a determination that the response for each point of the first group of points has been generated, moving the object to a position where a second group of points of the object corresponding to the coordinates in the second subset are accessible by the test contacts.

In one or more embodiments, the method further comprises displaying an image representing the set of coordinates for the object via a user interface. Displaying the image may further comprise: indicating, in a first color, a first coordinate in the first subset corresponding to the points for which the response has been generated, during the access to the first group of points. Displaying the image may further comprise indicating, in a second color, a second coordinate in the first subset corresponding to the points to be applied the input signal. In case that the second subset has been determined, displaying the image may further comprise indicating, in a third color, the coordinates of the second subset.

In one or more embodiments, the method further comprises determining whether the point is faulty based on the generated response. In response to determining that the point is faulty, initiating a further process to fix the faulty point and/or generating an alert associated with the faulty point.

In a second aspect, an apparatus for electrical test is provided. The apparatus for electrical test may comprise a platform, and a plurality of test devices. Each of the plurality of test devices may comprise a base, a plurality of test contacts extending from a first side of the base, and a post extending from a second side of the base opposite to the first side and configured to connect to the platform at a distal end of the post. Each test contact may comprise a first terminal for receiving an input signal and configured to contact an object to be tested, and a second terminal for outputting an output signal.

In one or more embodiments, the first terminal further comprises a conductive foam disposed on a distal end of the first terminal.

In one or more embodiments, the post comprises an elastomer so that the post is capable of retracting a distance under pressure and extending to restore when the pressure is removed.

In one or more embodiments, the apparatus may further comprise a plurality of switches. Each test contact is connected to a respective switch of the plurality of switches. The plurality of switches are configured to selectively switch on the test contacts.

In a third aspect, a system for electrical test is provided. The system may comprise the apparatus in the second aspect and a robot. The robot comprises one or more processors and a memory storing instructions thereon, which when executed by the processor, cause the robot to receive a set of coordinates for an object, and receive information indicating a number of test contacts of the apparatus. The instructions, when executed by the processor, further cause the robot to determine at least one subset of the received set of coordinates based on the number of the test contacts, select a first subset from the at least one subset, move the object to a position where a first group of points of the object corresponding to the coordinates in the first subset are accessible by the test contacts, enable application of an input signal to the first group of points, and enable generation of a response to an output signal relating to the input signal.

It is to be understood that the Summary is not intended to identify key or essential features of embodiments of the present disclosure, nor is it intended to be used to limit the scope of the present disclosure. Other features of the present disclosure will become easily comprehensible through the description below.

### BRIEF DESCRIPTION OF THE DRAWINGS

The above and other objectives, features and advantages of the present disclosure will become more apparent through more detailed depiction of example embodiments of the present disclosure in conjunction with the accompanying drawings, wherein in the example embodiments of the present disclosure, same reference numerals usually represent the same components.

FIG. 1 is a schematic diagram of a system for electrical test provided by the present disclosure;

FIG. 2 illustrates a system for electrical test according to an embodiment of the present disclosure;

FIG. 3 illustrates a system for electrical test according to another embodiment of the present disclosure;

FIG. 4 illustrates a flowchart of a process for electrical test according to an embodiment of the present disclosure;

FIG. 5A illustrates an image of a part of the object to be tested and a portion of a set of coordinates for the object;

FIG. 5B illustrates a subset of the set of coordinates for the object in FIG. 5A;

FIG. 6 illustrates a flowchart of a further process for electrical test according to an embodiment of the present disclosure;

FIG. 7A illustrates a circuit with a plurality of switches used in the system provided by the present disclosure;

FIG. 7B illustrates a further circuit with a switch network used in the system provided by the present disclosure;

FIG. 7C illustrates the test process for a subset shown FIG. 5B;

FIG. 8A illustrates an apparatus for electrical test according to an embodiment of the present disclosure; and

FIG. 8B illustrates a single test device of the apparatus illustrated in FIG. 8A.

Throughout the drawings, the same or similar reference symbols are used to indicate the same or similar elements.

### DETAILED DESCRIPTION

The present disclosure will now be discussed with reference to several example embodiments. It is to be understood these embodiments are discussed only for the purpose of enabling those skilled persons in the art to better understand and thus implement the present disclosure, rather than suggesting any limitations on the scope of the subject matter.

As used herein, the term “comprises” and its variants are to be read as open terms that mean “comprises, but is not limited to.” The term “based on” is to be read as “based at least in part on.” The term “one embodiment” and “an embodiment” are to be read as “at least one embodiment.” The term “another embodiment” is to be read as “at least one other embodiment.” The terms “first,” “second,” and the like may refer to different or same objects. Other definitions, explicit and implicit, may be comprised below. A definition of a term is consistent throughout the description unless the context clearly indicates otherwise.

Conventionally, there are two kinds of insulation detection methods for battery tray. One method is to use an insulation detection device and a manually operated detection tool. The manually operated detection tool is used to scan surfaces of the battery tray repeatedly. The existence of an unqualified or fault point in the insulation may be determined according to the readings on the insulation detection device. The disadvantage of this method is that only an approximate location of the unqualified point in the insulation may be determined due to the large detection area of the manually operated detection tool in each scan. It is impossible to determine an accurate location of the faulty point and thereby it will bring difficulties to the subsequent repair.

Another method is to use an industrial robot or other mechanical devices to hold the battery tray. The insulation detection device is connected to a coating surface of the battery tray via conductive wiring so as to detect the coating insulation performance of the battery tray. The disadvantage of this method is that only a few unqualified points can be found one time. After the detected faulty points are repaired, a next detection test has to be done for further check because the readings of the insulation detection device will reveal poor insulation performance as long as there is an unqualified point. The aforesaid test process will be performed repeatedly until the coating of the battery tray passes the insulation detection. The efficiency of this detection implementation is low and thereby the production efficiency of qualified battery trays cannot be guaranteed.

The present disclosure intends to provide a method for electrical test and a system for electrical test. The method and system according to the present disclosure improve the efficiency of detecting the faulty points and facilitates the further process for the detected faulty points, such as a repair process.

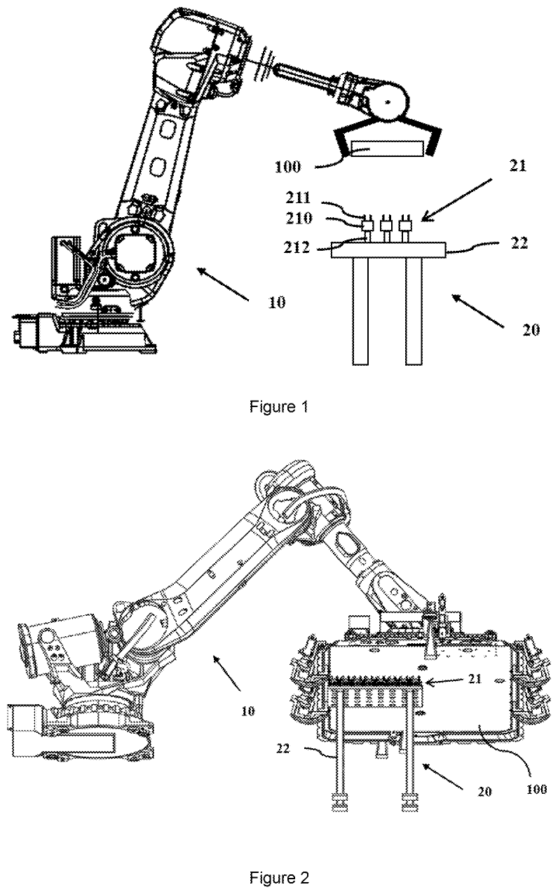

FIG. 1 is a schematic diagram of the system for electrical test provided by the present disclosure. Referring to FIG. 1, the system comprises a robot 10 and an apparatus 20 for electrical test. The robot 10 may be configured to grip an object 100 to be tested, such as the aforementioned battery tray. The robot 10 may comprise one or more processors and a memory. The robot 10 may be capable of wired or wireless communication with further devices, such as a computer storing the information associated with the object 100 to be tested and the information associated with the apparatus 20 for electrical test. The further devices may transmit the information about the object 100 to be tested and the information about the apparatus 20 for electrical test to the robot 10. As an alternative, the robot 10 may interact with an operator via a user interface. The operator may input the information about the object 100 to be tested and the information about the apparatus 20 for electrical test to the robot 10. The received information may be stored in the memory of the robot 10.

The information about the object 100 to be tested may at least comprise a set of coordinates for the object 100. Each coordinate in the set of coordinates may be mapped with a respective point on the object 100. The information about the apparatus 20 for electrical test may at least comprise information indicating a number of test contacts of the apparatus 20 for electrical test.

The apparatus 20 may comprise a plurality of test devices 21 and a platform 22. Each of the plurality of test devices may comprise a base 210, a plurality of test contacts 211, and a post. The plurality of test contacts 211 may be arranged to extend from a first side of the base 210. Each test contact 211 may comprise a first terminal for receiving an input signal and configured to contact an object to be tested, and a second terminal for outputting an output signal. The output signal is related to the input signal. The input signal and output signal may be electrical signal, such as voltage signal or current signal. In one example, both the input signal and the output signal are voltage signal. The area of the object 100 contacted by the first terminal, when the input signal is applied, will cause an abnormal signal decay and thus there is a greater difference between the input signal and the output signal, if the area does not have sufficient insulation performance. In contrast, the area of the object 100 contacted by the first terminal, when the input signal is applied, will cause little signal decay and thus the output signal may be approximately equal to the input signal, if the area has desired insulation performance.

The system may further comprise a power supply for generating an input signal and a tester for estimating electrical performance. The power supply may be coupled to the first terminal of test contacts 211 so as to feed the input signal. The tester may be coupled to the second terminal of the test contacts 211. The output signal may be transmitted to the tester for estimating electrical performance so as to enable the generation of a response to the output signals. The tester may comprise the insulation detection device, which is commercially available. The tester may be configured to generate the response to the output signal relating to the input signal. In case that the tester comprises the insulation detection device, the response may be indicative of the result of whether there is desired electrical performance. In another example, the tester may be configured to generate various responses of the electrical test. It may depend on the inherent function of the tester.

FIG. 2 illustrates a system for electrical test according to an embodiment of the present disclosure. In this embodiment, the apparatus 20 is stationary relative to the earth. The object 100 to be tested is held above the plurality of test devices 21. The object 100 may be moved relative to the test devices 21 by using the robot 10. The movement of the object 100 relative to the test devices 21 may enable the test of different areas of the surface of the object 100.

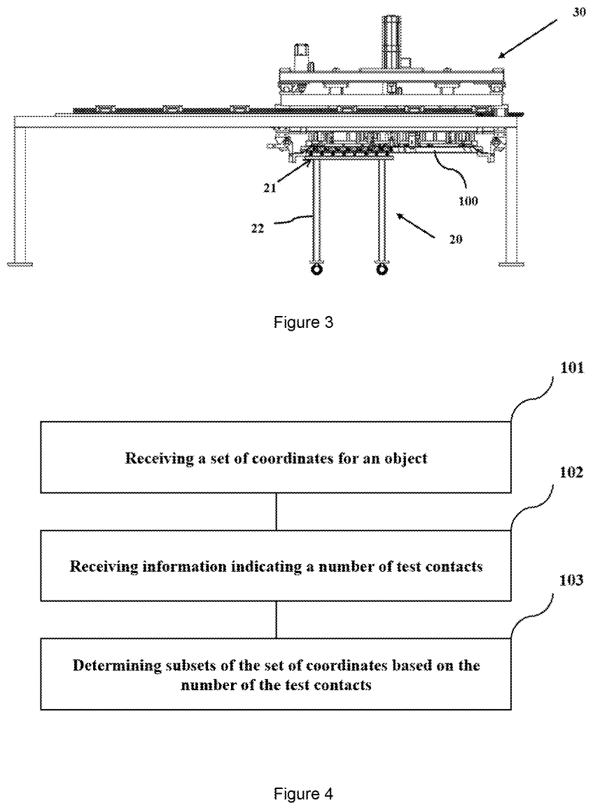

FIG. 3 illustrates a system for electrical test according to another embodiment of the present disclosure. In this embodiment, the object 100 is held by a framework 30 and kept stationary relative to the earth. The apparatus 20 comprises a wheel disposed on the bottom of the platform 22, as shown in FIG. 3. The apparatus 20 may be moved horizontally relative to the stationary object 100. The framework 30 may be equipped with a lifting mechanism configured to move upwards and downwards the object 100. With such an implementation, the detection for different areas of the surface of the object 100 by using the apparatus 20 is enabled.

FIG. 4 illustrates a flowchart of a process for electrical test according to an embodiment of the present disclosure.

At block 101, a set of coordinates for an object is received. At block 102, information indicating a number of test contacts is received. At block 103, a subset of the set of coordinates is determined based on the number of the test contacts.

In one example, based on the number of test contacts, the set of coordinates may be divided into a plurality of subsets. The criteria for dividing the set of coordinates into subsets may comprise that the number of coordinates in each subset should be equal or less than the number of test contacts. In one example, the total number of the test contacts is 160 and the number of coordinates in some of the subsets may be 160, and the number of coordinates in remainder of the subsets may be less than 160.

In addition, the criteria for dividing the set of coordinates into subsets may further comprise: the points corresponding to respective coordinates in the subset are accessible by the test contacts simultaneously. In this way, all the points corresponding to the coordinates in the subset may be tested in one time.

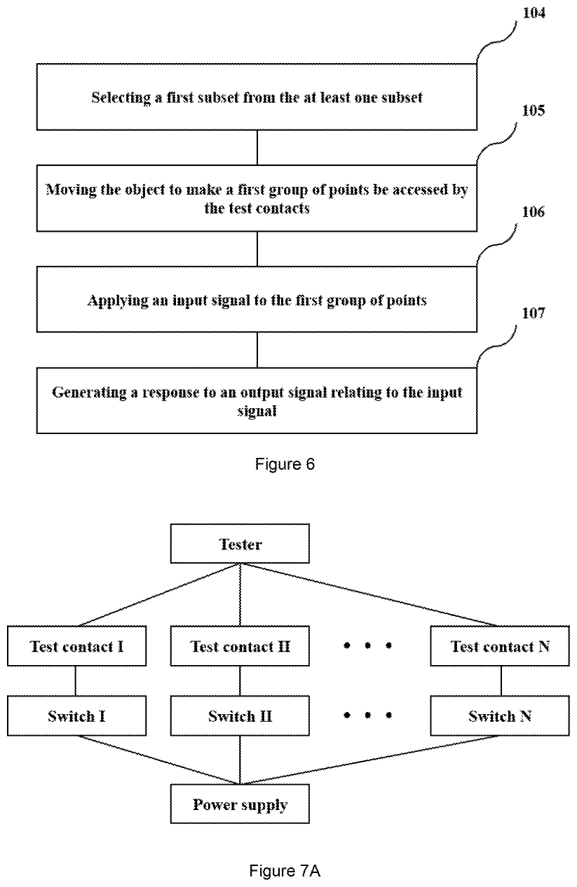

In one example, one single subset is determined from the plurality of subsets and used in the further processes, e.g. a process set forth below with reference to FIG. 6. Other subsets need not be determined and selected in a certain sequence before the test for the points of the object 100 corresponding to the chosen one single subset has been finished.

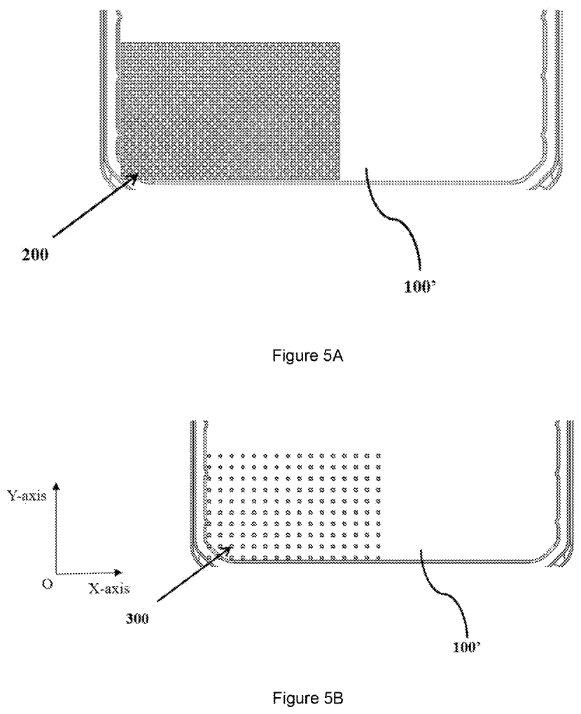

FIG. 5A illustrates an image of a part of the object to be tested and a portion of the set of coordinates for the object. FIG. 5B illustrates a subset of the set of coordinates for the object in FIG. 5A.

Referring to FIG. 5A, the illustrated object is a battery tray. An image 100′ of battery tray is displayed. The image 100′ may be displayed to the operator via a user interface. As shown in FIG. 5A, a portion of the image 100′ of the battery tray is overlapped with a grid. The grid represents a portion of a set of coordinates 200.

Referring to FIG. 5B, one example subset of coordinates 300 is illustrated. As shown, the coordinates are spaced apart from each other. In particular, there is a uniform interval between each pair of adjacent coordinates in the subset.

After at least one subset has been determined, the process for each subset of the at least one subset may be performed. FIG. 6 illustrates a flowchart of the further process for electrical test according to an embodiment of the present disclosure.

At block 104, a first subset is selected from the at least one subset. In an example, the subset of coordinates 300 illustrated in FIG. 5B may be the selected as the first subset. In another example, the first subset 300 is selected based on the location of the test contacts. The first subset may be determined in such a way that the points of the object corresponding to coordinates in the first subset have the overall closest distance to the test contacts. The overall distance to the test contact may be the accumulative sum of each point in the subset to the respective test contact. In a further example, the first subset 300 may be determined as an initial subset for starting the test and the points of the object corresponding to coordinates in the first subset comprises the points on the edge and/or in the corner of the object.

At block 105, the object may be moved to a position where a first group of points of the object corresponding to the coordinates in the first subset are accessible by the test contacts. Each of the test contacts may be moved to approach the surface of the object and abut against the corresponding points.

At block 106, an input signal may be applied to the first group of points. The input signal may be a voltage signal or a current signal. The input signal may be provided by a power supply coupled to a first terminal of the test contacts.

With the applied input signal, the corresponding points on the object may be energized. At block 107, a response to an output signal relating to the input signal may be generated. The response may be generated by using a tester for estimating electrical performance coupled to a second terminal of the test contacts. The response may be an electrical signal. The electrical signal may be compared with a reference to determine the electrical performance of a point in the first group of points. Additionally or alternatively, the response may comprise an indicator which is representative of whether the point is a faulty point. The point may be marked as a faulty point based on a predefined criterion. For example, the predefined criterion is that the point has a worse electrical performance than a desired electrical performance.

In addition, the method may further comprise determining whether the point is faulty based on the generated response. In response to determining that the point is faulty, the method may comprise initiating a further process to fix the faulty point and/or generating an alert associated with the faulty point.

In one example, the faulty points may comprise unqualified insulation points. The present disclosure further provides two repair schemes for the unqualified insulation points. One is using insulation paint or other suitable materials to repair the unqualified points. Another method is to paste insulation tape on the unqualified points. These repair schemes may be done by the robot or manually.

An alert associated with the faulty points may be used to inform the operator of the existence of the faulty points. The alert may comprise audible signals, visible signals, or a combination thereof.

In one example, applying an input signal to the first group of points further comprises: in response to a determination that one subset of the at least one subset comprises same coordinates as included in the first subset, disabling the application of the input signal to the points corresponding to the same coordinates. In this way, the points on the object may not be tested repeatedly and thereby less energy from the power supply may be consumed during the test.

Determining whether the one subset comprises the same coordinates as included in the first subject may be performed by comparing the subset in the plurality of subsets with each other. As an alternative, the subset comprising the same coordinates as included in other one or more subsets may be marked when dividing the set of coordinates into a plurality of subsets. Then, a comparison of the marked subset with other subsets is performed and the same coordinates are identified. In this way, it facilitates the process of finding the same coordinates simultaneously included in at least two subsets.

In one example, the method further comprises determining a second subset based on a similarity between the first subset and other subset of the at least one subset. In case that the coordinates are coordinates in a two dimensional coordinate system, the similarity is related to at least one of an x-axis coordinate of the coordinates of the first subset, or a y-axis coordinate of the coordinates of the first subset. For example, the subset comprising coordinate (100, 100) may be regarded as being more similar to the first subset comprising coordinate (100, 50) than the subset comprising coordinate (200, 200). In this example, the similarity is estimated based at least in part on the x-axis coordinate. In another example, the second subset may be an “offset” first subset. Namely, the second subset may be determined by offsetting the x-axis coordinate, y-axis coordinate, or both for each element in the first subset. The offset between the first subset and the second subset may be predefined. The offset may comprise various offsets. In one example, the offset comprises a first offset and a second offset. The first offset may be determined based on the maximum difference between the coordinates of the first subset. The second offset may be determined based on the distance in the coordinate system corresponding to the width of one single test contact. In this way, all the points on the object may be tested.

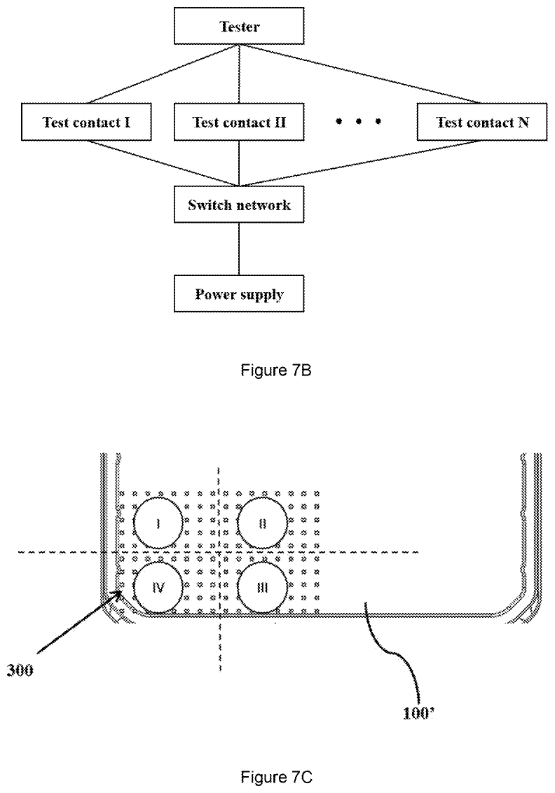

FIG. 7A illustrates a circuit with a plurality of switches used in the system provided by the present disclosure. FIG. 7B illustrates a further circuit with a switch network used in the system provided by the present disclosure.

Referring to FIG. 7A, a plurality of switches are provided between the power supply and the test contacts. Each of the plurality of switches may be connected to a respective test contact. When applying the input signal to the first group of points, the plurality of switches are operative to selectively switch on the test contacts. The plurality of switches may be replaced with a switch network, as shown in FIG. 7B. All the test contacts may be connected to the switch network. The switch network may be configured to selectively switch on the test contacts in response to a control signal.

By utilizing the plurality of the switches or the switch network, when applying the input signal to the first group of points, a portion of the test contacts may be enabled, and simultaneously the remainder of the test contacts may be disabled. FIG. 7C illustrates the test process for a subset shown FIG. 5B. Area II may be tested following area I has been tested. When the test to the points located in area II is performed, the test contacts corresponding to the area II are enabled and other test contacts corresponding to area I, III, IV are disabled.

Additionally or alternatively, the number of the test contacts to be enabled may be determined based on a rated operating power of the power supply and the level of the input signal. This provides benefit when there are many test contacts and the power supply configured to provide the input signal has limited rated operating power.

The method further comprises, in response to a determination that the response for each point of the first group of points has been generated, moving the object to a position where a second group of points of the object corresponding to the coordinates in the second subset are accessible by the test contacts. Then, the electrical test for the points of the object corresponding to the coordinates in the second subset may be performed, similar with the process discussed above with reference to FIG. 6.

Similar with the transition from the process for the first subset to the process for the second subset, the transition from the process for the second subset to the process for a further subset in the plurality of subsets may be performed. The further process of test for the points corresponding to the coordinates in the further subset may be the same as the process described above with reference to FIG. 6. In this way, the electrical test for each point on the object may be done.

In addition, during the electrical test, an image representing the set of coordinates for the object may be displayed via a user interface. While displaying the image, a first coordinate in the first subset corresponding to the points for which the response has been generated, may be indicated in a first color. A second coordinate in the first subset corresponding to the points to be applied by the input signal may be indicated in a second color. The coordinates of the second subset may be indicated in a third color. The first, second and third colors may be different from each other. For example, the first color may be red, the second color may be blue, and the third color may be yellow. In this way, the progress of the test may be displayed on the user interface and thus the operator may learn the stage of the electrical test in real time.

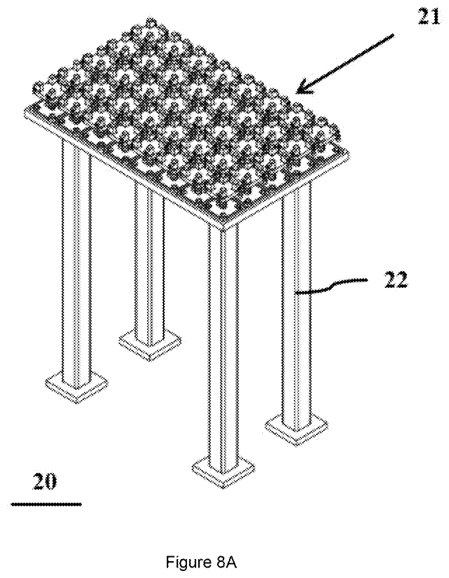

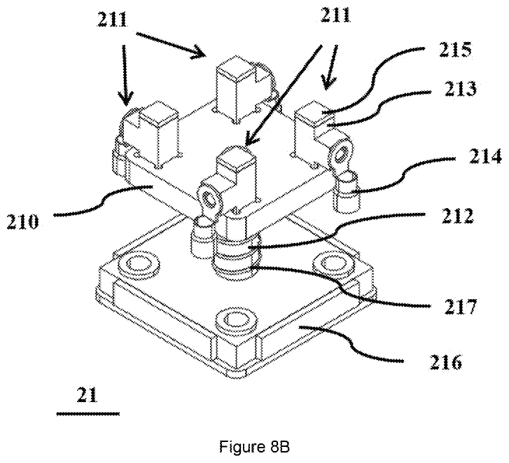

To further facilitate the electrical test, the present disclosure provides an apparatus for electrical test. FIG. 8A illustrates the apparatus for electrical test according to an embodiment of the present disclosure. FIG. 8B illustrates a single test device of the apparatus illustrated in FIG. 8A.

Referring to FIGS. 8A-8B, the apparatus 20 may comprise a platform 22, and a plurality of test devices 21. Each of the plurality of test devices 21 may comprise a base 210, a plurality of test contacts 211 and a post 212. The test contacts 211 may be arranged to extend from a first side of the base 210. Each of the test contacts 211 comprises a first terminal 213 and a second terminal 214.

The post 212 may be arranged to extend from a second side of the base 210 opposite to the first side. The post 212 may be configured to connect to the platform at a distal end of the post 212. Additionally, the test device may comprise a flat bottom portion 216. The flat bottom portion 216 may be fixedly connected to the platform via fasteners.

In one example, the first terminal 213 further comprises a conductive foam 215 disposed on a distal end of the first terminal 213. When the first terminal 213 abuts against the surface of the object at the respective point, the conductive foam 215 may deform according to the profile of the contacted surface, and thus there is sufficient contact between the first terminal 213 of the test contacts and the surface of the object, so as to avoid the poor conductivity and increased resistance.

The post 212 may further comprise an elastomer. The elastomer may be retracted and extended based on the application and release of the pressure thereon. In case that each of the plurality of test devices 21 comprises a post 212 comprising an elastomer, a sufficient pressure may be applied to the plurality of test devices 21, and thereby the post 212 of each test device 21 may be retracted in different magnitudes such that all the test contacts may abut against the surface of the object.

In one example, a spring 217 is provided between the flat bottom portion 216 and the base 210. In particular, the post 212 is surrounded by the spring 217. The spring 217 may facilitate the extension of the post 212 when the applied pressure is removed and thus the post 212 may restore to original position faster.

It will be appreciated that the embodiments of the invention also apply to computer programs, particularly computer programs on or in a carrier, adapted to put the invention into practice.

The program may be in the form of a source code, an object code, a code intermediate source and an object code such as in a partially compiled form, or in any other form suitable for use in the implementation of the method according to embodiments of the invention. It will also be appreciated that such a program may have many different architectural designs. For example, a program code implementing the functionality of the method or system according to the invention may be sub-divided into one or more sub-routines. Many different ways of distributing the functionality among these sub routines will be apparent to the skilled person. The sub-routines may be stored together in one executable file to form a self-contained program. Such an executable file may comprise computer-executable instructions, for example, processor instructions and/or interpreter instructions (e.g. Java interpreter instructions). Alternatively, one or more or all of the sub-routines may be stored in at least one external library file and linked with a main program either statically or dynamically, e.g. at run-time. The main program contains at least one call to at least one of the sub-routines. The sub-routines may also comprise function calls to each other. An embodiment relating to a computer program product comprises computer-executable instructions corresponding to each processing stage of at least one of the methods set forth herein. These instructions may be sub-divided into sub-routines and/or stored in one or more fries that may be linked statically or dynamically. Another embodiment relating to a computer program product comprises computer-executable instructions corresponding to each means of at least one of the systems and/or products set forth herein. These instructions may be sub-divided into sub-routines and/or stored in one or more files that may be linked statically or dynamically.

The carrier of a computer program may be any entity or device capable of carrying the program. For example, the carrier may include a data storage, such as a ROM, for example, a CD ROM or a semiconductor ROM, or a magnetic recording medium, for example, a hard disk. Furthermore, the carrier may be a transmissible carrier such as an electric or optical signal, which may be conveyed via electric or optical cable or by radio or other means. When the program is embodied in such a signal, the carrier may be constituted by such a cable or other device or means. Alternatively, the carrier may be an integrated circuit in which the program is embedded, the integrated circuit being adapted to perform, or used in the performance of, the relevant method.

Variations to the disclosed embodiments can be understood and effected by those skilled in the art in practicing the principles and techniques described herein, from a study of the drawings, the disclosure and the appended claims. In the claims, the word “comprising” does not exclude other elements or steps, and the indefinite article “a” or “an” does not exclude a plurality. A single processor or other unit may fulfil the functions of several items recited in the claims. The mere fact that certain measures are recited in mutually different dependent claims does not indicate that a combination of these measures cannot be used to advantage. A computer program may be stored or distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

1. A method for electrical test comprising:
receiving a set of coordinates for an object,
receiving information indicating a number of test contacts of an apparatus for the electrical test,
determining, based on the number of the test contacts, at least one subset of the received set of coordinates,
selecting a first subset from the at least one subset,
moving the object to a position where a first group of points of the object corresponding to the coordinates in the first subset are accessible by the test contacts,
applying an input signal to the first group of points, and
generating a response to an output signal relating to the input signal.

2. The method of claim 1, wherein applying an input signal to the first group of points further comprising:
in response to a determination that one subset of the at least one subset comprises same coordinates as included in the first subset, disabling the application of the input signal to the points corresponding to the same coordinates.

3. The method of claim 1, further comprising:
determining, based on a similarity between the first subset and another subset of the at least one subset, a second subset.

4. The method of claim 3, wherein the coordinates are coordinates in a two dimensional coordinate system; and
wherein the similarity is related to at least one of:
an x-axis coordinate of the coordinates of the first subset, or
a y-axis coordinate of the coordinates of the first subset.

5. The method of claim 1, further comprising:
determining, based on the first subset and a predefined offset, a second subset.

6. The method of claim 1, wherein the number of the coordinates in each of the at least one subset corresponds to the number of test contacts.

7. The method of claim 1, wherein applying the input signal to the first group of points further comprises:
enabling a portion of the test contacts, and simultaneously disabling the remainder of the test contacts.

8. The method of claim 3, further comprising:
in response to a determination that the response for each point of the first group of points has been generated, moving the object to a position where a second group of points of the object corresponding to the coordinates in the second subset are accessible by the test contacts.

9. The method of claim 3, further comprising:
displaying an image representing the set of coordinates for the object via a user interface.

10. The method of claim 9, wherein displaying the image further comprising:
indicating, in a first color, a first coordinate in the first subset corresponding to the points for which the response has been generated, during the access to the first group of points;
indicating, in a second color, a second coordinate in the first subset corresponding to the points to be applied the input signal; and
indicating, in a third color, the coordinates of the second subset.

11. The method claim 10, further comprising:
determining whether the point is faulty based on the generated response, and
in response to determining that the point is faulty, initiating a further process to fix the faulty point and/or generating an alert associated with the faulty point.

12. An apparatus for electrical test, comprising:
a platform,
a plurality of test devices, each of which includes:
a base;
a plurality of test contacts extending from a first side of the base, and each having:
a first terminal for receiving an input signal and configured to contact an object to be tested; and
a second terminal for outputting an output signal, and
a post extending from a second side of the base opposite to the first side and configured to connect to the platform at a distal end of the post.

13. The apparatus of claim 12, wherein the first terminal further comprises a conductive foam disposed on a distal end of the first terminal.

14. The apparatus of claim 12, wherein the post comprises an elastomer and/or the test device comprises a spring surrounding the post.

15. The apparatus of claim 12, further comprising a plurality of switches, and
wherein each test contact is connected to a respective switch of the plurality of switches,
wherein the plurality of switches is configured to selectively switch on the test contacts.

16. A system for electrical test, comprising:
an apparatus for electrical test including:
receiving a set of coordinates for an object,
receiving information indicating a number of test contacts of an apparatus for the electrical test,
determining, based on the number of the test contacts, at least one subset of the received set of coordinates,
selecting a first subset from the at least one subset,
moving the object to a position where a first group of points of the object corresponding to the coordinates in the first subset are accessible by the test contacts,
applying an input signal to the first group of points, and
generating a response to an output signal relating to the input signal;
a robot having one or more processors and a memory storing instructions thereon, which when executed by the processor, cause the robot to:
receive a set of coordinates for an object,
receive information indicating a number of test contacts of the apparatus, determine, based on the number of the test contacts, at least one subset of the received set of coordinates,
select a first subset from the at least one subset,
move the object to a position where a first group of points of the object corresponding to the coordinates in the first subset are accessible by the test contacts,
enable application of an input signal to the first group of points, and
enable generation of a response to an output signal relating to the input signal.
